(19) United States
(12) Patent Application Publication
(10) Pub. No.: US 2024/0300848 A1
(43) Pub. Date: Sep. 12, 2024

(54) GLASS SUBSTRATE FOR SPACE-BASED SOLAR POWER GENERATION

(71) Applicant: NIPPON ELECTRIC GLASS CO., LTD., Shiga (JP)

(72) Inventors: Koichi HASHIMOTO, Shiga (JP); Takashi MURATA, Shiga (JP)

(21) Appl. No.: 18/576,588

(22) PCT Filed: Aug. 9, 2022
(86) PCT No.: PCT/JP2022/030449

§ 371 Date: Jan. 4, 2024

(30) Foreign Application Priority Data
Aug. 17, 2021 (JP) 2021-132633

(51) Int. Cl. C03C 3/095; C03C 4/08

(52) U.S. Cl. CPC C03C 3/095; C03C 4/085

(57) ABSTRACT

Provided is a glass substrate that can suppress solarization, and can also suppress deterioration of a resin caused by intense ultraviolet light even when the glass substrate is thinned. A glass substrate for space solar power generation of the present invention has a sheet thickness of 0.2 mm or less and has a content of TiO₂ of from 0.001 mass % to 10 mass % in a glass composition.

### TECHNICAL FIELD

The present invention relates to a glass substrate for space solar power generation.

### BACKGROUND ART

In recent years, communication networks utilizing satellites have been actively formed. As powder supply sources for those satellites, the use of solar power generation has been investigated. As a solar cell used for the solar power generation, there are known various types based on polycrystalline Si, monocrystalline Si, a thin film compound, GaAs, and the like. Moreover, in each of those solar cells, a cover glass for protecting a device thereof is bonded to a power generation device through intermediation of a resin layer (see Patent Literatures 1 and 2).

### CITATION LIST

Patent Literature 1: JP 2002-173098 A
Patent Literature 2: JP 2022-089141 A

### SUMMARY OF INVENTION

### Technical Problem

When the solar cell is used for a long period of time, there arises a problem in that the cover glass is discolored by ultraviolet light, and the intensity of solar light radiated to a solar cell device is reduced, with the result that desired conversion efficiency is not obtained (the problem is hereinafter referred to as “solarization”).

In addition, there arises another problem in that a resin used between the cover glass and the power generation device is deteriorated through irradiation with intense ultraviolet light (e.g., ultraviolet light at a wavelength of 250 nm) during stay in space, with the result that power generation efficiency is reduced. In particular, a glass substrate is required to be thinned so that the glass substrate may be launched into space, but its ultraviolet light transmittance is increased owing to the thinning, which accelerates the deterioration of the resin.

The present invention has been made in view of the above-mentioned circumstances, and an object of the present invention is to provide a glass substrate that can suppress solarization, and can also suppress deterioration of a resin caused by intense ultraviolet light even when the glass substrate is thinned.

### Solution to Problem

The inventors of the present invention have made various investigations, and as a result, have found that the above-mentioned technical object can be achieved by introducing, as an essential component, at least one of TiO₂ or CeO₂ in an appropriate amount into a glass composition of a glass substrate for space solar power generation. Thus, the finding is proposed as the present invention.

In a glass substrate for space solar power generation according to one aspect of the present invention, TiO₂ is introduced into a glass composition as an essential component, and thus the above-mentioned technical object can be achieved. That is, according to a first aspect of the present invention, there is provided a glass substrate for space solar power generation, which has a sheet thickness of 0.2 mm or less and has a content of TiO₂ of from 0.001 mass % to 10 mass % in a glass composition.

In addition, according to a second aspect of the present invention, in the glass substrate for space solar power generation according to the first aspect of the present invention, it is preferred that the glass substrate have a content of TiO₂ of from 0.005 mass % to 10 mass % in the glass composition, and when the sheet thickness is represented by “t” and the content of TiO₂ in the glass composition is represented by B, the glass substrate have a ratio B/t of 5 mass %/mm or more.

In addition, according to a third aspect of the present invention, in the glass substrate for space solar power generation according to the first or second aspect of the present invention, it is preferred that the glass substrate have a sheet thickness of 0.2 mm or less and comprise as the glass composition, in terms of mass %, 50% to 80% of SiO₂, 3% to 25% of Al₂O₃, 0% to 20% of B₂O₃, 0% to 25% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, and 0.005% to 10% of TiO₂.

In addition, according to a fourth aspect of the present invention, in the glass substrate for space solar power generation according to any one of the first to third aspects of the present invention, it is preferred that the glass substrate have a mass ratio SnO₂/(As₂O₃+SnO₂) of from 0.90 to 1 in the glass composition.

In addition, according to a fifth aspect of the present invention, in the glass substrate for space solar power generation according to any one of the first to fourth aspects of the present invention, it is preferred that when the sheet thickness is represented by “t” and a mass ratio SnO₂/(As₂O₃+SnO₂) in the glass composition is represented by A, the glass substrate have a ratio A/t of 1/mm or more.

In addition, according to a sixth aspect of the present invention, in the glass substrate for space solar power generation according to any one of the first to fifth aspects of the present invention, it is preferred that when a transmittance of the glass substrate at a wavelength of 300 nm at a thickness of 0.05 mm after irradiation with ultraviolet light at 254 nm (13 mW/cm²) for 23 hours is represented by t300 (%), and a transmittance of the glass substrate at a wavelength of 300 nm at a thickness of 0.05 mm before the irradiation with ultraviolet light is represented by T300 (%), the glass substrate have a value for T300-t300 of 3% or less.

In addition, according to a seventh aspect of the present invention, in the glass substrate for space solar power generation according to any one of the first to sixth aspects of the present invention, it is preferred that the glass substrate have a transmittance at a wavelength of 250 nm at a thickness of 0.05 mm of 30% or less.

In addition, according to an eighth aspect of the present invention, in the glass substrate for space solar power generation according to any one of the first to seventh aspects of the present invention, it is preferred that the glass substrate have an average transmittance at a wavelength of from 400 nm to 1,000 nm at a thickness of 0.05 mm of 90% or more.

In addition, according to a ninth aspect of the present invention, in the glass substrate for space solar power generation according to any one of the first to eighth aspects of the present invention, it is preferred that the glass substrate have a density of 2.80 g/cm³ or less. Herein, the “density” refers to a value obtained through measurement by a well-known Archimedes method.

In addition, according to a tenth aspect of the present invention, in the glass substrate for space solar power generation according to any one of the first to ninth aspects of the present invention, it is preferred that the glass substrate have a liquidus viscosity of 10^{4.0} dPa·s or more. Herein, the “liquidus viscosity” refers to the viscosity of glass at a liquidus temperature.

In addition, according to an eleventh aspect of the present invention, in the glass substrate for space solar power generation according to any one of the first to tenth aspects of the present invention, it is preferred that the glass substrate have a coefficient of thermal expansion at from 30° C. to 380° C. of from 25×10⁻⁷/° C. to 90×10⁻⁷/° C. Herein, the “coefficient of thermal expansion” refers to a value obtained by measuring an average coefficient of thermal expansion at from 30° C. to 380° C. with a dilatometer.

In addition, according to a twelfth aspect of the present invention, in the glass substrate for space solar power generation according to any one of the first to eleventh aspects of the present invention, it is preferred that the glass substrate have a content of Fe₂O₃ of 500 ppm by mass or less.

In addition, according to a thirteenth aspect of the present invention, in the glass substrate for space solar power generation according to any one of the first to twelfth aspects of the present invention, it is preferred that the glass substrate be formed by an overflow down-draw method.

In addition, according to a fourteen aspect of the present invention, in the glass substrate for space solar power generation according to any one of the first to thirteenth aspects of the present invention, it is preferred that the glass substrate comprise as the glass composition, in terms of mass %, 50% to 80% of SiO₂, 3% to 20% of Al₂O₃, 0% to 20% of B₂O₃, 5% to 20% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, and 2% to 10% of TiO₂.

In addition, according to a fifteenth aspect of the present invention, in the glass substrate for space solar power generation according to the first or second aspect of the present invention, it is preferred that the glass substrate comprise as the glass composition, in terms of mass %, 50% to 80% of SiO₂, 3% to 25% of Al₂O₃, 0% to 20% of B₂O₃, 0.01% to 25% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, 0.001% to 10% of TiO₂, and 0.001% to 10% of CeO₂.

Further, in a glass substrate for space solar power generation according to another aspect of the present invention, CeO₂ is introduced into a glass composition as an essential component, and thus the above-mentioned technical object can be achieved. That is, according to a sixteenth aspect of the present invention, there is provided a glass substrate for space solar power generation, which has a sheet thickness of 0.2 mm or less and comprises as a glass composition, in terms of mass %, 54% to 80% of SiO₂, 4% to 25% of Al₂O₃, 0.1% to 20% of B2O₃, 0% to 25% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, 0% to 10% of TiO₂, and 0.001% to 10% of CeO₂.

### DESCRIPTION OF EMBODIMENTS

A glass substrate for space solar power generation according to one aspect of the present invention preferably comprises as a glass composition, in terms of mass %, 50% to 80% of SiO₂, 3% to 25% of Al₂O₃, 0% to 20% of B₂O₃, 0% to 25% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, and 0.001% to 10% of TiO₂. In addition, a glass substrate for space solar power generation according to another aspect of the present invention preferably has a sheet thickness of 0.2 mm or less and comprises as a glass composition, in terms of mass %, 54% to 80% of SiO₂, 4% to 25% of Al₂O₃, 0.1% to 20% of B₂O₃, 0% to 25% of Li₂O+Na₂O+K₂O, 0% to 20% of MgO, 0% to 20% of Cao, 0% to 20% of SrO, 0% to 20% of BaO, 0% to 1% of As₂O₃, 0.0001% to 2% of SnO₂, 0% to 10% of TiO₂, and 0.001% to 10% of CeO₂. The reasons why the content ranges of the components are limited as described above are described below. In the following description, the expression “%” represents “mass %” unless otherwise specified.

SiO₂ is a component that forms a network. The content thereof is preferably from 50% to 80%, from 53% to 75%, or from 54% to 70%, particularly preferably from 55% to 65%. When the content of SiO₂ is large, there are tendencies that: a viscosity at high temperature is increased, with the result that meltability is reduced; and devitrification stones of cristobalite are liable to precipitate. Meanwhile, when the content of SiO₂ is small, weather resistance is reduced, and vitrification becomes difficult.

Al₂O₃ is a component that increases a strain point and a Young's modulus, and suppresses precipitation of the devitrification stones of cristobalite. The content thereof is preferably from 3% to 25%, from 4% to 24%, from 5% to 23%, from 6% to 21%, from 7% to 20%, from 9% to 19%, or from 11% to 18%, particularly preferably from 13% to 17%. When the content of Al₂O₃ is large, there is a tendency that a liquidus temperature is increased, with the result that it becomes difficult to form glass into a thin sheet. Meanwhile, when the content of Al₂O₃ is small, there are tendencies that the strain point and the Young's modulus are reduced, and the viscosity at high temperature is increased, with the result that the meltability is reduced.

B₂O₃ is a component that acts as a melting accelerate component, and reduces a viscosity to improve the meltability. The content thereof is preferably from 0% to 20%, from 0.1% to 18%, from 0.5% to 17%, from 1% to 16%, from 3% to 15%, from 5% to 14%, from 6% to 13%, or from 7% to 12%, particularly preferably from 8% to 11%. When the content of B₂O₃ is large, there are tendencies that the strain point and the Young's modulus are reduced, and the weather resistance is reduced. Meanwhile, when the content of B₂O₃ is small, the liquidus temperature is increased, with the result that it becomes difficult to form the glass into a thin sheet. In addition, there is a tendency that the viscosity at high temperature is increased, with the result that the meltability is reduced. In addition, a glass surface is liable to be flawed.

Li₂O, Na₂O, and K₂O are each a component that controls a coefficient of thermal expansion, and reduces the viscosity at high temperature. The total content of those components (Li₂O+Na₂O+K₂O) is preferably from 0% to 25%, from 0.001% to 20%, from 1% to 19%, from 3% to 18%, from 5% to 18%, from 8% to 18%, or from 10% to 17%, particularly preferably from 12% to 17%. When the total content of those components is large, the strain point is reduced, with the result that heat resistance is liable to be reduced. In addition, the coefficient of thermal expansion is excessively increased, and its matching property with that of a peripheral member may be impaired. The content of Li₂O is preferably from 0% to 10%, from 0% to 8%, from 0% to 5%, from 0% to 3%, or from 0% to 1%, particularly preferably from 0% to 0.5%. The content of Na₂O is preferably from 0% to 25%, from 0.1% to 24%, from 1% to 22%, from 3% to 21%, from 5% to 20%, from 8% to 18%, or from 10% to 17%, particularly preferably from 12% to 16%. The content of K₂O is preferably from 0% to 10%, from 0% to 8%, from 0% to 5%, from 0% to 3%, or from 0% to 1%, particularly preferably from 0.1% to 0.5%.

MgO is a component that improves the meltability without reducing the strain point. The content thereof is preferably from 0% to 20%, from 0% to 15%, from 0% to 12%, from 0% to 10%, from 0% to 7%, from 0% to 5%, or from 0.1% to 3%, particularly preferably from 0.5% to 2%. When the content of MgO is large, the liquidus temperature is increased, with the result that it becomes difficult to form the glass into a thin sheet. In addition, the coefficient of thermal expansion is increased, and its matching property with that of a peripheral member is impaired. In addition, the density is increased. Meanwhile, when the content of MgO is small, the strain point and the Young's modulus are reduced, and the viscosity at high temperature is increased, with the result that it becomes difficult to melt the glass.

Cao is a component that improves the meltability without reducing the strain point. The content thereof is preferably from 0% to 20%, from 0.01% to 18%, from 0.1% to 15%, from 1% to 12%, or from 2% to 10%, particularly preferably from 3% to 9%. When the content of Cao is large, the liquidus temperature is increased, with the result that it becomes difficult to form the glass. In addition, the coefficient of thermal expansion is increased, and its matching property with that of a peripheral member is impaired. In addition, the density is increased. Meanwhile, when the content of Cao is small, the strain point and the Young's modulus are reduced, and the viscosity at high temperature is increased, with the result that it becomes difficult to melt the glass.

SrO is a component that improves the meltability without reducing the strain point. The content thereof is preferably from 0% to 20%, from 0.001% to 15%, from 0.1% to 12%, from 0.3% to 9%, or from 0.4% to 8%, particularly preferably from 0.5% to 7%. When the content of SrO is large, the liquidus temperature is increased, with the result that it becomes difficult to form the glass. In addition, the coefficient of thermal expansion is increased, and its matching property with that of a peripheral member is impaired. In addition, the density is increased. Meanwhile, when the content of SrO is small, the strain point and the Young's modulus are reduced, and the viscosity at high temperature is increased, with the result that it becomes difficult to melt the glass.

BaO is a component that reduces the viscosity at high temperature to improve the meltability without reducing the strain point. In addition, BaO is a component that increases the Young's modulus. Meanwhile, when the content of BaO is large, the liquidus temperature is increased, with the result that it may become difficult to form the glass. In addition, the coefficient of thermal expansion is increased, and its matching property with that of a peripheral member may be impaired. In addition, the density may be increased. Accordingly, the content of BaO is preferably from 0% to 20%, from 0% to 15%, from 0% to 10%, from 0% to 8%, or from 0% to 5%, particularly preferably from 0% to 3%.

Alkaline earth metal oxides, such as MgO, Cao, SrO, and BaO, can each improve the meltability and devitrification resistance by being mixed to be incorporated in the glass substrate. However, when the content of those components is large, there is a tendency that the density is increased, and it becomes difficult to achieve weight saving of the glass substrate. Accordingly, the total content of the alkaline earth metal oxides (MgO+CaO+SrO+BaO) is preferably from 0% to 30%, from 0% to 25%, from 0% to 20%, from 0% to 18%, from 0% to 15%, or from 0% to 12%, particularly preferably from 0% to 10%.

The total content of Cao, SrO, and BaO, that is, CaO+SrO+BaO is preferably from 0% to 10%, from 0% to 7%, from 0% to 8%, from 0% to 5%, from 0% to 3%, from 0% to 2%, or from 0% to 18, particularly preferably from 0% to 0.18. When the content of those components is large, there is a tendency that the density is increased, and it becomes difficult to achieve weight saving of the glass substrate.

The content of Fe₂O₃ is from 0% to 0.05%, preferably from 0.0001% to 0.05%, from 0.0001% to 0.03%, or from 0.005% to 0.02%, particularly preferably from 0.005% to 0.015%. When the content of Fe₂O₃ is large, a visible light transmittance is excessively reduced, and the amount of solar light radiated to a solar cell device is reduced. Besides, solarization is liable to occur. When the content of Fe₂O₃ is small, an ultraviolet light transmittance is increased, which leads to deterioration of a resin present on the substrate, with the result that the lifetime of a solar cell may be shortened.

As₂O₃ is a fining agent, but is a component that promotes the solarization. The content thereof is preferably from 0% to 1%, from 0% to 0.8%, from 0% to 0.5%, or from 0% to 0.3%, particularly preferably from 0% to 0.005%.

SnO₂ is a component that suppresses the solarization. The content of SnO₂ is preferably from 0.0001% to 2%, from 0.001% to 1.5%, from 0.01% to 1%, or from 0.05% to 0.5%, particularly preferably from 0.05% to 0.3%. When the content of SnO₂ is large, the devitrification resistance is liable to be reduced. Meanwhile, when the content of SnO₂ is small, it becomes difficult to exhibit the above-mentioned effect. A SnO₂ raw material may be used as a source of SnO₂, but SnO₂ may be incorporated from a trace component in another raw material or the like.

In order to reliably exhibit a suppressing effect on the solarization, it is important to strictly regulate a mass ratio SnO₂/(As₂O₃+SnO₂). A value for the mass ratio SnO₂/(As₂O₃+SnO₂) is preferably from 0.001 to 1, from 0.01 to 1, from 0.1 to 1, from 0.3 to 1, from 0.5 to 1, from 0.7 to 1, or from 0.9 to 1, particularly preferably 1.

TiO₂ and CeO₂ are each a component that reduces the ultraviolet light transmittance, and has a suppressing effect on the solarization. Accordingly, in any aspect of the present invention, the glass substrate for space solar power generation comprises at least one of TiO₂ or CeO₂ in the glass composition. Accordingly, the total content of TiO₂ and CeO₂, that is, TiO₂+CeO₂ is from 0.001% to 20%, from 0.005% to 18%, from 0.01% to 15%, from 0.02% to 14%, from 0.1% to 13%, from 0.5% to 12%, from 1% to 11%, from 2% to 10%, or from more than 2.5% to 8%, particularly from more than 3% to 7%. When the “TiO₂+CeO₂” is too large, the devitrification resistance is liable to be reduced.

TiO₂ is a component that reduces the ultraviolet light transmittance, and has a suppressing effect on the solarization. The content of TiO₂ is preferably from 0% to 10%, from 0.001% to 10%, from 0.005% to 9.5%, from 0.01% to 9%, from 0.015% to 8.8%, from 0.02% to 8.5%, from 0.1% to 8%, from 0.3% to 7.5%, from more than 0.4% to 7%, from 0.5% to 7%, from 0.8% to 6.5%, from 1% to 6%, from 1.5% to 5.5%, or from 1.8% to 5%, particularly preferably from 2% to 4.5%. When the content of TiO₂ is large, the devitrification resistance is liable to be reduced. In addition, a transmittance in a visible region may be reduced. The glass substrate for space solar power generation according to the one aspect of the present invention comprises TiO₂ as an essential component (that is, the content of TiO₂ is 0.001% or more). Meanwhile, the glass substrate for space solar power generation according to the other aspect of the present invention comprises CeO₂ as an essential component, and in this case, does not need to comprise TiO₂ as an essential component.

CeO₂ is a component that reduces the ultraviolet light transmittance, and has a suppressing effect on the solarization. The content thereof is preferably from 0% to 10%, from 0.001% to 9%, from 0.02% to 8%, from 0.1% to 7.5%, from 0.3% to 7%, from 0.5% to 6%, from 0.8% to 6.5%, from 1% to 6%, from 1.5% to 5.5%, or from 1.8% to 5%, particularly preferably from 2% to 4.5%. When the content of CeO₂ is large, the devitrification resistance is liable to be reduced. In addition, the transmittance in the visible region may be reduced. The glass substrate for space solar power generation according to the one aspect of the present invention comprises, as the glass composition, TiO₂ as an essential component, and in this case, does not need to comprise CeO₂ as an essential component. Meanwhile, the glass substrate for space solar power generation according to the other aspect of the present invention does not necessarily comprise TiO₂ as the glass composition, and in this case, comprises CeO₂ as an essential component (that is, the content of CeO₂ is 0.001% or more).

In addition to the above-mentioned components, other components may be introduced as required in terms of total content.

ZnO is a component that increases the Young's modulus and improves the meltability. The content thereof is preferably from 0% to 10%, more preferably from 0% to 5%, still more preferably from 0% to 3%, particularly preferably from 0% to 1%, most preferably from 0% to 0.5%. When the content of ZnO is large, the density and the coefficient of thermal expansion are liable to be increased. In addition, there are tendencies that the devitrification resistance and the strain point are reduced.

Zro₂ is a component that improves the weather resistance. The content thereof is preferably from 0% to 2%, more preferably from 0% to 18, still more preferably from 0% to 0.5%, particularly preferably from 0% to 0.2%, most preferably from 0.001% to 0.1%. When the content of Zro₂ is large, there is a tendency that devitrification stones of zircon precipitate.

Sb₂O₃ is a component that acts as a fining agent. The content thereof is preferably from 0% to 2%, more preferably from 0% to 1.5%, still more preferably from 0% to 1%, particularly preferably from 0% to 0.5%. When the content of Sb₂O₃ is large, there is a tendency that the density is increased.

Cl is a component that acts as a fining agent. The content thereof is preferably from 0% to 18, more preferably from 0% to 0.5%. When the content of Cl is large, evaporation from a glass melt is increased, and cords are liable to be generated.

Rare earth oxides, such as Nb₂O₅ and La₂O₃, are each a component that increases the Young's modulus. However, raw materials thereof have high cost in themselves, and the rare earth oxides are each also a component that reduces the devitrification resistance. Accordingly, the content of the rare earth oxides is preferably 3% or less, 2% or less, 1% or less, particularly 0.5% or less.

The glass substrate for space solar power generation of the present invention has a sheet thickness of 0.2 mm or less, preferably 0.15 mm or less, 0.1 mm or less, 0.07 mm or less, or 0.05 mm or less, particularly preferably 0.04 mm or less. As the sheet thickness becomes smaller, more weight saving of the glass substrate can be achieved.

In the glass substrate for space solar power generation of the present invention, when the sheet thickness is represented by “t” and the mass ratio SnO₂/(As₂O₃+SnO₂) in the glass composition is represented by A, a ratio A/t is preferably 1/mm or more, 3/mm or more, 5/mm or more, 7/mm or more, 10/mm or more, or 12/mm or more, particularly preferably from 15/mm to 1,000/mm. When the ratio A/t is too low, it becomes difficult for the glass substrate to achieve both the solarization resistance and weight saving.

In the glass substrate for space solar power generation of the present invention, when the sheet thickness is represented by “t” and the content of TiO₂ in the glass composition is represented by B, a ratio B/t is preferably 5 mass %/mm or more, 8 mass %/mm or more, 10 mass %/mm or more, 15 mass %/mm or more, 20 mass %/mm or more, 25 mass %/mm or more, 30 mass %/mm or more, 35 mass %/mm or more, 40 mass %/mm or more, 42 mass/mm or more, 45 mass %/mm or more, 50 mass %/mm or more, 52 mass %/mm or more, 55 mass %/mm or more, 58 mass %/mm or more, 60 mass %/mm or more, 62 mass %/mm or more, 65 mass %/mm or more, or 68 mass %/mm or more, particularly preferably from 70 mass %/mm to 1,000 mass %/mm. When the ratio B/t is too low, in the case where the sheet thickness of the glass substrate is reduced (e.g., 0.2 mm or less), it becomes difficult to obtain a sufficient ultraviolet light shielding property and the solarization resistance.

The glass substrate for space solar power generation of the present invention preferably has an unpolished surface. The theoretical strength of glass is originally extremely high, but breakage often occurs even with a stress that is by far lower than the theoretical strength. This is because a small defect called Griffith flaw is generated on the surface of a glass substrate in steps after forming of the glass, for example, in a polishing step. When the surface of the glass substrate, in particular, the entirety of each of both the surfaces thereof is unpolished, the original mechanical strength of the glass substrate is less liable to be impaired, and the glass substrate is less liable to be broken. In addition, when the surface of the glass substrate is unpolished, the polishing step can be omitted in a production process for the glass substrate, and hence the production cost of the glass substrate can be reduced. In addition, chamfering processing, etching processing, or the like may be performed on the cut surface of the glass substrate in order to prevent such a situation that breakage occurs from the cut surface of the glass substrate.

The glass substrate for space solar power generation of the present invention may be produced as follows: glass raw materials blended so as to give a desired glass composition are loaded into a continuous melting furnace, heated to be melted at from 1,500° C. to 1, 600° C., and fined; after that, the molten glass is supplied to a forming apparatus and formed into a sheet shape, followed by annealing.

The glass substrate for space solar power generation of the present invention is preferably formed by an overflow down-draw method. When the glass substrate is formed by an overflow down-draw method, a glass substrate having satisfactory surface quality can be produced without polishing. The reason for this is as follows: in the case of the overflow down-draw method, a surface to serve as the surface of the glass substrate is not brought into contact with the surface of a trough-shaped refractory, and is formed in the state of a free surface, and thus the glass substrate having satisfactory surface quality can be produced without polishing. Herein, the overflow down-draw method is a method involving causing molten glass to overflow from both sides of a heat-resistant trough-shaped structure, and subjecting the overflowing molten glasses to down-draw downward while the molten glasses are merged at the lower end of the trough-shaped structure, to thereby produce a glass substrate.

Various methods other than the overflow down-draw method may each be adopted as a forming method. For example, various forming methods, such as a float method, a slot down method, a re-draw method, a roll out method, and a press method, may each be adopted.

The glass substrate for space solar power generation of the present invention may be subjected to, for example, surface processing such as provision of a film, or mechanical processing, such as cutting or drilling, as required. For example, an antireflection film may be used as a film that can be used in the surface processing. The use of such film can reduce the reflection loss of the glass substrate.

In addition, it is preferred that a compressive stress layer through ion exchange be prevented from being formed in the surface of the glass substrate for space solar power generation of the present invention because various optical characteristics of the glass substrate may be impaired, and when the sheet thickness is small, warping of the glass substrate may be increased.

The glass substrate for space solar power generation of the present invention preferably satisfies the following characteristics.

The “T300-t300” is a parameter related to solarization resistance for near-ultraviolet light (at a wavelength of from 200 nm to 380 nm). Herein, the “T300” refers to the transmittance (%) of the glass substrate at a wavelength of 300 nm at a thickness of 0.05 mm, and the “t300” refers to the transmittance (%) of the glass substrate at a wavelength of 300 nm at a thickness of 0.05 mm after the glass substrate is irradiated with ultraviolet light at 254 nm (13 mW/cm²) for 23 hours. In addition, the “T300-t300” refers to a value obtained by subtracting t300 from T300. A value for T300-t300 is preferably 3% or less, 2.5% or less, 2% or less, 1.8% or less, 1.5% or less, 1.2% or less, 1.0% or less, 0.8% or less, 0.7% or less, 0.6% or less, or 0.5% or less, particularly preferably from −1% to 0.3%. As the value for T300-t300 becomes smaller, solarization caused by near-ultraviolet light can be suppressed more. In addition, in particular, ultraviolet light around a wavelength of 250 nm is significantly intense, and hence may remarkably accelerate the deterioration of a resin used between the glass substrate and a power generation device in a solar cell. Accordingly, as the value for T300-t300 becomes smaller, the deterioration of the resin in the solar cell can be suppressed more, and the solar cell maintains high energy conversion efficiency more easily. The value for T300-t300 is not always positive, and may be negative.

The “T300-t′ 300” is a parameter related to solarization resistance for far-ultraviolet light (at a wavelength of from 10 nm to 200 nm). Herein, the “t′300” refers to the transmittance (%) of the glass substrate at a wavelength of 300 nm at a thickness of 0.05 mm after the glass substrate is irradiated with ultraviolet light at 185 nm (13 mW/cm²) for 23 hours. In addition, the “T300-t′300” refers to a value obtained by subtracting t′300 from T300. A value for T300-t′300 is preferably 3% or less, 2.5% or less, 2% or less, 1.8% or less, 1.5% or less, 1.2% or less, 1.0% or less, 0.8% or less, 0.7% or less, 0.6% or less, or 0.5% or less, particularly preferably from −1% to 0.3%. As the value for T300-t′300 becomes smaller, solarization caused by far-ultraviolet light can be suppressed more. Accordingly, the solar cell maintains high energy conversion efficiency more easily. The value for T300-t′300 is not always positive, and may be negative.

A transmittance T250 at a wavelength of 250 nm at a thickness of 0.05 is a characteristic indicating an ultraviolet light shielding property. T250 is preferably 30% or less, 25% or less, 20% or less, 15% or less, 10% or less, 8% or less, or 5% or less, particularly preferably from 0% to 1%. When T250 is too high, it becomes difficult to sufficiently shield ultraviolet light. Accordingly, when being irradiated with intense ultraviolet light during stay in space, a resin used between the glass substrate and a power generation device is deteriorated by the ultraviolet light, and power generation efficiency is liable to be reduced.

An average transmittance at a wavelength of from 400 nm to 1,000 nm at a sheet thickness of 0.05 mm is preferably 90% or more, particularly preferably 91% or more. When the average transmittance at a wavelength of from 400 nm to 1,000 nm at a sheet thickness of 0.05 mm is too low, the power generation efficiency is liable to be reduced.

The strain point is preferably 500° C. or more, more preferably 550° C. or more, still more preferably 600° C. or more, particularly preferably 630° C. or more. As the strain point becomes higher, the heat resistance of the glass substrate is increased more, and deformation or the like of the glass substrate due to a significant temperature change in space is less liable to occur.

The liquidus temperature is preferably 1,200° C. or less, 1,150° C. or less, 1, 120° C. or less, 1, 100° C. or less, or 1,090° C. or less, particularly preferably 1,070° C. or less. As the liquidus temperature becomes lower, the glass is less liable to devitrify at the time of forming by an overflow down-draw method or the like.

The liquidus viscosity is preferably 10^{4.0} dPa·s or more, 10^{4.5} dPa·s or more, 10^{5.0} dPa·s or more, 10^{5.3} dPa·s or more, or 10^{5.5} dPa·s or more, particularly preferably 10^{5.7} dPa·s or more. As the liquidus viscosity becomes higher, the glass is less liable to devitrify at the time of forming by an overflow down-draw method or the like.

In the glass substrate for space solar power generation of the present invention, when the sheet thickness is represented by “t”, and log η, which is the logarithm of the liquidus viscosity n of the glass, is represented by C, a ratio C/t is preferably 70/mm or more, 75/mm or more, 80/mm or more, 85/mm or more, 90/mm or more, or 95/mm or more, particularly preferably from 100/mm to 150/mm. When the ratio C/t is too low, the glass is liable to devitrify at the time of forming of a glass substrate having a small sheet thickness (e.g., 0.2 mm or less) by an overflow down-draw method or the like.

The density is preferably 2.80 g/cm³ or less, 2.70 g/cm³ or less, 2.65 g/cm³ or less, 2.60 g/cm³ or less, 2.55 g/cm³ or less, or 2.50 g/cm³ or less, particularly preferably 2.45 g/cm³ or less. As the density becomes lower, more weight saving of the glass substrate can be achieved. As a result, its use in space is facilitated.

The coefficient of thermal expansion at from 30° C. to 380° C. is preferably from 25×10⁻⁷/° C. to 90×10⁻⁷/° C., from 30×10⁻⁷/° C. to 85×10⁻⁷/° C., from 35×10⁻⁷/° C. to 83×10⁻⁷/° C., from 40×10⁻⁷/° C. to 80×10⁻⁷/° C., or from 45×10⁻⁷/° C. to 78×10⁻⁷/° C., particularly preferably from 50×10⁻⁷/° C. to 75×10⁻⁷/° C. When the coefficient of thermal expansion is outside the above-mentioned ranges, it becomes difficult to match the coefficient of thermal expansion with that of a peripheral member, such as a metal or an organic adhesive, and it becomes difficult to prevent peeling of the peripheral member, such as a metal or an organic adhesive.

A temperature at a viscosity at high temperature of 10^{2.5} dPa·s is preferably 1,700° C. or less, 1, 650° C. or less, or 1,600° C. or less, particularly preferably 1,550° C. or less. As the temperature at a viscosity at high temperature of 10^{2.5} dPa·s becomes lower, a burden on a glass production facility such as a melting kiln is reduced more, and besides, the bubble quality of the glass substrate can be improved more. That is, the temperature at a viscosity at high temperature of 10^{2.5} dPa·s becomes lower, the glass substrate can be produced more inexpensively.

The Young's modulus is preferably 68 GPa or more or 69 GPa or more, particularly preferably 70 GPa or more. As the Young's modulus becomes higher, the glass substrate is less liable to be deflected.

A specific Young's modulus is preferably 27 GPa/(g/cm³) or more, 28 GPa/(g/cm³) or more, or 29 GPa/(g/cm³) or more, particularly preferably 30 GPa/(g/cm³) or more. As the specific Young's modulus becomes higher, the deflection of the glass substrate due to its own weight is reduced more.

### Example 1

Now, the present invention is described by way of Examples.

Examples of the present invention (Sample Nos. 1 to 20) are shown in Tables 1 to 3. In the tables, the “A/t” refers to a value obtained by dividing a value for A by a value for “t” when a mass ratio SnO₂/(As₂O₃+SnO₂) in a glass composition is represented by A and a sheet thickness is represented by “t”. In addition, the “B/t” refers to a value obtained by dividing a value for B by a value for “t” when the content of TiO₂ in the glass composition is represented by B and the sheet thickness is represented by “t”. Further, the “C/t” refers to a value obtained by dividing a value for C by a value for “t” when log η, which is the logarithm of the liquidus viscosity n of glass, is represented by C and the sheet thickness is represented by “t”.

TABLE 1

| [mass %] | No. 1 | No. 2 | No. 3 | No. 4 | No. 5 | No. 6 | No. 7 |
|---|---|---|---|---|---|---|---|
| SiO₂ | 63.7 | 63.0 | 64.2 | 58.3 | 57.5 | 57.3 | 59.4 |
| Al₂O₃ | 13.4 | 13.3 | 13.5 | 16.1 | 16.0 | 15.8 | 16.8 |
| B₂O₃ | 2.4 | 2.5 | 2.5 | 9.5 | 9.4 | 9.1 | 10.0 |
| Li₂O | 0.0096 | 0.0095 | 0.0097 | 0.00 | 0.00 | 0.00 | 0.00 |
| Na₂O | 12.9 | 12.6 | 13.0 | 0.00 | 0.00 | 0.00 | 0.00 |
| K₂O | 0.56 | 0.53 | 0.56 | 0.00 | 0.00 | 0.00 | 0.00 |
| MgO | 2.8 | 2.8 | 2.85 | 0.28 | 0.28 | 0.28 | 0.29 |
| CaO | 0.03 | 0.06 | 0.03 | 7.8 | 7.75 | 7.65 | 8.11 |
| SrO | 0.001 | 0.02 | <0.001 | 4.3 | 4.26 | 4.21 | 4.48 |
| BaO | 0.007 | 0.008 | 0.008 | 0.58 | 0.58 | 0.58 | 0.59 |
| ZnO | <0.001 | <0.001 | <0.001 | <0.001 | <0.001 | <0.001 | <0.001 |
| As₂O₃ | 0.000 | 0.000 | 0.000 | 0.000 | 0.000 | 0.000 | 0.000 |
| Sb₂O₃ | <0.001 | <0.001 | <0.001 | <0.001 | <0.001 | <0.001 | <0.001 |
| SnO₂ | 0.33 | 0.33 | 0.33 | 0.17 | 0.17 | 0.17 | 0.18 |
| ZrO₂ | 0.003 | 0.004 | 0.003 | 0.002 | 0.002 | 0.003 | 0.001 |
| Fe₂O₃ | 0.013 | 0.013 | 0.013 | 0.008 | 0.008 | 0.008 | 0.008 |
| TiO₂ | 3.80 | 4.70 | 2.84 | 2.88 | 3.83 | 4.72 | 0.004 |
| SnO₂/(As₂O₃ + SnO₂) | 1.000 | 1.000 | 1.000 | 1.000 | 1.000 | 1.000 | 1.000 |
| Li₂O + Na₂O + K₂O | 13.470 | 13.140 | 13.570 | 0.000 | 0.000 | 0.000 | 0.000 |
| A/t [/mm] | 20.00 | 20.00 | 20.00 | 20.00 | 20.00 | 20.00 | 20.00 |
| B/t [mass %/mm] | 76.00 | 94.00 | 56.80 | 57.60 | 76.60 | 94.40 | 0.08 |
| Density [g/cm³] | 2.45 | 2.46 | 2.45 | 2.48 | 2.49 | 2.5 | 2.46 |
| Coefficient of | 78 | 77 | 78 | 38 | 38 | 38 | 39 |
| thermal expansion | | | | | | | |
| [×10⁻⁷/° C.] | | | | | | | |
| Strain point [° C.] | 558 | 559 | 558 | 656 | 653 | 651 | 654 |
| Annealing point | 601 | 601 | 602 | 709 | 704 | 701 | 709 |
| [° C.] | | | | | | | |
| Softening point | 814 | 812 | 819 | 933 | 926 | 922 | 944 |
| [° C.] | | | | | | | |
| 10^{4.0} dPa · s [° C.] | 1,198 | 1,202 | 1,215 | 1,236 | 1,232 | 1,220 | 1,268 |
| 10^{3.0} dPa · s [° C.] | 1,410 | 1,411 | 1,427 | 1,396 | 1,391 | 1,378 | 1,428 |
| 10^{2.5} dPa · s [° C.] | 1,543 | 1,543 | 1,561 | 1,501 | 1,494 | 1,477 | 1,532 |
| Liquidus | 960 | 1,005 | 947 | 1,164 | 1,196 | Unmeasured | 1,084 |
| temperature [° C.] | | | | | | | |
| Liquidus | 5.8 | 5.4 | 6.0 | 4.6 | 4.3 | Unmeasured | 5.7 |
| viscosity [logη] | | | | | | | |
| C/t [logη/mm] | 116.0 | 108.0 | 120.0 | 92.0 | 86.0 | Unmeasured | 114.0 |
| Transmittance | 0.0 | 0.0 | 0.0 | 0.0 | 0.0 | 0.0 | 76.1 |
| T250 [%] | | | | | | | |
| Transmittance | 42.1 | 25.1 | 55.9 | 54.5 | 34.0 | 13.7 | 88.8 |
| T300 [%] | | | | | | | |
| Transmittance | 90.7 | 90.5 | 91.0 | 90.5 | 90.3 | 90.1 | 91.0 |
| T400 [%] | | | | | | | |
| Transmittance | 91.5 | 91.4 | 91.7 | 91.2 | 91.1 | 91.0 | 91.6 |
| T550 [%] | | | | | | | |
| Transmittance | 92.0 | 92.0 | 92.2 | 91.8 | 91.7 | 91.6 | 92.1 |
| T1000 [%] | | | | | | | |
| Transmittance | 0.0 | 0.0 | 0.0 | 0.0 | 0.0 | 0.0 | 75.7 |
| t250 [%] | | | | | | | |
| Transmittance | 42.2 | 25.4 | 55.6 | 54.7 | 34.1 | 14.1 | 88.1 |
| t300 [%] | | | | | | | |
| Transmittance | 90.8 | 90.6 | 91.0 | 90.5 | 90.4 | 90.1 | 91.0 |
| t400 [%] | | | | | | | |
| Transmittance | 91.5 | 91.3 | 91.6 | 91.2 | 91.1 | 90.9 | 91.5 |
| t550 [%] | | | | | | | |
| Transmittance | 92.1 | 92.0 | 92.2 | 91.8 | 91.7 | 91.6 | 92.1 |
| t1000 [%] | | | | | | | |
| T300 − t300 [%] | −0.1 | −0.3 | 0.3 | −0.2 | −0.1 | −0.4 | 0.7 |

TABLE 2

| [mass %] | No. 8 | No. 9 | No. 10 | No. 11 | No. 12 | No. 13 | No. 14 | No. 15 | No. 16 |
|---|---|---|---|---|---|---|---|---|---|
| SiO₂ | 64.793 | 63.935 | 62.7603 | 64.1 | 63.511 | 63.021 | 63.992 | 63.824 | 63.723 |
| Al₂O₃ | 14 | 14 | 14.1 | 13.1 | 13.2 | 13.1 | 13.2 | 13.2 | 13.2 |
| B₂O₃ | 2.6 | 2.5 | 2.5 | 2.5 | 2.5 | 2.5 | 2.5 | 2.6 | 2.6 |
| Li₂O | 0.01 | 0.01 | 0.01 | 0.01 | 0.01 | 0.01 | 0.01 | 0.01 | 0.01 |
| Na₂O | 12.7 | 12.7 | 12.8 | 11.9 | 11.9 | 12 | 11.9 | 12 | 12.1 |
| K₂O | 0.53 | 0.53 | 0.53 | 0.53 | 0.52 | 0.53 | 0.52 | 0.52 | 0.52 |
| MgO | 3.00 | 3.00 | 3.02 | 2.75 | 2.76 | 2.75 | 2.77 | 2.76 | 2.78 |
| CaO | 0.03 | 0.03 | 0.03 | 0.02 | 0.02 | 0.02 | 0.02 | 0.02 | 0.02 |
| SrO | 0.00 | 0.00 | 0.00 | 0.00 | 0.00 | 0.00 | 0.00 | 0.00 | 0.00 |
| BaO | 0.01 | 0.01 | 0.01 | 0.01 | 0.01 | 0.009 | 0.01 | 0.009 | 0.009 |
| SnO₂ | 0.34 | 0.33 | 0.33 | 0.33 | 0.33 | 0.33 | 0.33 | 0.33 | 0.33 |
| ZrO₂ | 0.004 | 0.003 | 0.004 | 0.003 | 0.003 | 0.003 | 0.002 | 0.001 | 0.002 |
| Fe₂O₃ | 0.014 | 0.014 | 0.014 | 0.007 | 0.006 | 0.007 | 0.006 | 0.006 | 0.006 |
| TiO₂ | 0.019 | 0.018 | 0.0017 | 4.7 | 4.72 | 4.72 | 4.22 | 3.72 | 2.72 |
| CeO₂ | 1.95 | 2.92 | 3.89 | 0.00 | 0.48 | 0.96 | 0.49 | 0.97 | 1.95 |
| Cl | 0.00 | 0.00 | 0.00 | 0.04 | 0.03 | 0.04 | 0.03 | 0.03 | 0.03 |
| TiO₂ + CeO₂ | 1.969 | 2.938 | 3.892 | 4.700 | 5.200 | 5.680 | 4.710 | 4.690 | 4.670 |
| SnO₂/(As₂O₃ + SnO₂) | 1.000 | 1.000 | 1.000 | 1.000 | 1.000 | 1.000 | 1.000 | 1.000 | 1.000 |
| Li₂O + Na₂O + K₂O | 13.240 | 13.240 | 13.340 | 12.440 | 12.430 | 12.540 | 12.430 | 12.530 | 12.630 |
| A/t [/mm] | 20.00 | 20.00 | 20.00 | 20.00 | 20.00 | 20.00 | 20.00 | 20.00 | 20.00 |
| B/t [mass %/mm] | 0.38 | 0.36 | 0.034 | 94 | 94.4 | 94.4 | 84.4 | 74.4 | 54.4 |
| Density [g/cm³] | 2.45 | 2.47 | 2.49 | 2.45 | 2.46 | 2.47 | 2.46 | 2.46 | 2.47 |
| Coefficient of | 76.7 | 78 | 78.2 | 74.2 | 74.5 | 75.2 | 73.9 | 74.5 | 75 |
| thermal expansion | | | | | | | | | |
| [×10⁻⁷/° C.] | | | | | | | | | |
| Strain point [° C.] | 568 | 568 | 569 | 560 | 564 | 564 | 564 | 564 | 566 |
| Annealing point [° C.] | 616 | 615 | 616 | 602 | 608 | 607 | 607 | 607 | 610 |
| Softening point [° C.] | 851.5 | 848 | 844.5 | 820 | 832 | 822 | 826 | 826.5 | 832 |
| 10^{4.0} dPa · s [° C.] | 1,248 | 1,246 | 1,231 | 1,217 | 1,216 | 1,204 | 1,224 | 1,218 | 1,222 |
| 10^{3.0} dPa · s [° C.] | 1,454 | 1,450 | 1,433 | 1,426 | 1,423 | 1,408 | 1,431 | 1,426 | 1,428 |
| 10^{2.5} dPa · s [° C.] | 1,585 | 1,580 | 1,560 | 1,557 | 1,553 | 1,536 | 1,561 | 1,556 | 1,560 |
| Liquidus temperature | >1,174 | >1,175 | >1,183 | 1,040 | 1,049 | 1,038 | 1,017 | >1,168 | >1,183 |
| [° C.] | | | | | | | | | |
| Liquidus viscosity | <4.45 | <4.43 | <4.29 | 5.19 | 5.16 | 5.15 | 5.44 | <4.30 | <4.23 |
| [logη] | | | | | | | | | |
| C/t [° C./mm] | <89.0 | <88.6 | <85.8 | 103.8 | 103.2 | 103.0 | 108.8 | <86.0 | <84.6 |

TABLE 3

| [mass %] | No. 17 | No. 18 | No. 19 | No. 20 |
|---|---|---|---|---|
| SiO₂ | 64.237 | 63.318 | 62.088 | 61.317 |
| Al₂O₃ | 6.98 | 7.97 | 9.01 | 9.98 |
| B₂O₃ | 7.5 | 7.5 | 7.4 | 7.4 |
| Li₂O | 0.00 | 0.00 | 0.00 | 0.00 |
| Na₂O | 11.1 | 11.1 | 11.2 | 11.1 |
| K₂O | 0.00 | 0.00 | 0.00 | 0.00 |
| MgO | 0.004 | 0.003 | 0.003 | 0.003 |
| CaO | 0.007 | 0.007 | 0.007 | 0.008 |
| SrO | 0.01 | 0.01 | 0.01 | 0.01 |
| BaO | 3.96 | 3.98 | 3.98 | 3.97 |
| SnO₂ | 0.38 | 0.39 | 0.38 | 0.39 |
| ZrO₂ | 0.001 | 0.001 | 0.001 | 0.001 |
| Sb₂O₃ | 0.001 | <0.001 | <0.001 | <0.001 |
| TiO₂ | 1.02 | 1.02 | 1.02 | 1.02 |
| CeO₂ | 4.8 | 4.70 | 4.90 | 4.80 |
| Cl | 0.00 | 0.00 | 0.00 | 0.00 |
| TiO₂ + CeO₂ | 5.820 | 5.720 | 5.920 | 5.820 |
| SnO₂/(As₂O₃ + SnO₂) | 1.000 | 1.000 | 1.000 | 1.000 |
| Li₂O + Na₂O + K₂O | 11.100 | 11.100 | 11.200 | 11.100 |
| A/t [/mm] | 20.00 | 20.00 | 20.00 | 20.00 |
| B/t [mass %/mm] | 20.4 | 20.4 | 20.4 | 20.4 |
| Density [g/cm³] | 2.57 | 2.57 | 2.56 | 2.56 |
| Coefficient of thermal | 69.7 | 70.3 | 70.4 | 70.4 |
| expansion [×10⁻⁷/° C.] | | | | |
| Strain point [° C.] | 538 | 538 | 539 | 539 |
| Annealing point [° C.] | 575 | 575 | 577 | 577 |
| Softening point [° C.] | 746 | 747 | 750 | 752 |
| 10^{4.0} dPa · s [° C.] | 1,085 | 1,057 | 1,080 | 1,077 |
| 10^{3.0} dPa · s [° C.] | 1,288 | 1,250 | 1,288 | 1,277 |
| 10^{2.5} dPa · s [° C.] | 1,430 | 1,386 | 1,425 | 1,412 |
| Liquidus temperature | 1,000 | 1,044 | 1,092 | Unmea- |
| [° C.] | | | | sured |
| Liquidus viscosity [logη] | 4.6 | 4.4 | 3.9 | Unmea- |
| | | | | sured |
| C/t [° C./mm] | 92 | 88 | 78 | Unmea- |
| | | | | sured |
| Transmittance T250 [%] | 0.0 | 0.0 | 0.0 | 0.0 |
| Transmittance T300 [%] | 0.1 | 0.1 | 0.1 | 0.1 |
| Transmittance T400 [%] | 88.9 | 88.4 | 88.1 | 87.5 |
| Transmittance T550 [%] | 91.3 | 91.1 | 91.2 | 91.1 |
| Transmittance T1000 [%] | 92.1 | 92.0 | 92.1 | 92.1 |
| Transmittance t250 [%] | 0.0 | 0.0 | 0.0 | 0.0 |
| Transmittance t300 [%] | 0.1 | 0.1 | 0.1 | 0.1 |
| Transmittance t400 [%] | 87.5 | 88.8 | 88.4 | 87.6 |
| Transmittance t550 [%] | 91.2 | 91.4 | 91.2 | 90.8 |
| Transmittance t1000 [%] | 92.2 | 92.2 | 92.0 | 91.8 |
| T300 − t300 [%] | 0.0 | 0.0 | 0.0 | 0.0 |

Each of the samples was produced as described below.

First, glass raw materials were blended so as to have glass compositions shown in Tables 1 to 3, and melted with a platinum pot at 1,600° C. for 8 hours. After that, the molten glass was cast onto a carbon sheet and formed into a sheet shape. Various properties were evaluated for the resultant glass substrate.

The density refers to a value obtained through measurement by a well-known Archimedes method.

The coefficient of thermal expansion refers to a value obtained by measuring an average coefficient of thermal expansion at from 30° C. to 380° C. with a dilatometer.

The strain point Ps and the annealing point Ta refer to values obtained through measurement based on a method of ASTM C336.

The softening point Ts refers to a value obtained through measurement based on a method of ASTM C338.

The temperatures at viscosities 10^{4.0} dPa·s, 10^{3.0} dPa·s, and 10^{2.5} dPa·s of glass refer to values obtained through measurement by a platinum sphere pull up method.

The liquidus temperature refers to a value obtained by measuring a temperature at which crystals deposit when glass is pulverized, and glass powder, which has passed through a standard 30-mesh sieve (sieve opening: 500 μm) and remained on a 50-mesh sieve (sieve opening: 300 μm), is placed in a platinum boat, and is kept in a temperature gradient furnace for 24 hours. The liquidus viscosity refers to a value obtained by measuring the viscosity of glass at the liquidus temperature by a platinum sphere pull up method.

The transmittances refer to values obtained by measuring respective values before and after irradiation with predetermined ultraviolet light as described below. A glass sample having a thickness of 0.05 mm is subjected to precision optical processing, and then its transmittances at wavelengths of 250 nm, 300 nm, 400 nm, 550 nm, and 1,000 nm (referred to as “T250”, “T300”, “T400”, “T550”, and “T1000”, respectively) are measured with UV-3100PC (manufactured by Shimadzu Corporation). After that, the glass sample is irradiated with ultraviolet light at 254 nm (13 mW/cm²) for 23 hours. Next, after the ultraviolet light irradiation, its transmittances at wavelengths of 250 nm, 300 nm, 400 nm, 550 nm, and 1,000 nm (referred to as “t250”, “t300”, “t400”, “t550”, and “t1000”, respectively) are measured.

As apparent from the tables above, each of Sample Nos. 1 to 7 and 17 to 20 had a low value for T300-t300 of 0.7% or less. In particular, each of Sample Nos. 1 to 6 and 17 to 20 had a value for T250 of 0.0%, and was found to be glass that achieved both solarization resistance and an ultraviolet light shieling property. In addition, each of Sample Nos. 8 to 17 contains 1.969% or more of TiO₂+CeO₂. Accordingly, it is conceived that each of Sample Nos. 8 to 17 similarly has low values for T300-t300 and T250, and is glass that achieves both solarization resistance and an ultraviolet light shieling property.

### Example 2

First, glass raw materials were blended so as to give a glass composition shown in each of Sample Nos. 1 to 20 in the tables, and were then supplied to a glass melting furnace and melted at 1,600° C. Next, the molten glass was supplied to an overflow down-draw forming apparatus and formed into a sheet thickness of 0.10 mm. Thus, a film-shaped glass substrate was obtained. The represent glass substrate was subjected to cut processing into a predetermined size, and was then subjected to slimming into a sheet thickness of 0.05 mm through surface etching. Thus, a glass substrate for space solar power generation was obtained.

1. A glass substrate for space solar power generation, which has a sheet thickness of 0.2 mm or less and has a content of TiO₂ of from 0.001 mass % to 10 mass % in a glass composition.

2. The glass substrate for space solar power generation according to claim 1,
wherein the glass substrate has a content of TiO₂ of from 0.005 mass % to 10 mass % in the glass composition, and
wherein when the sheet thickness is represented by “t” and the content of TiO₂ in the glass composition is represented by B, the glass substrate has a ratio B/t of 5 mass %/mm or more.

3. The glass substrate for space solar power generation according to claim 1, wherein the glass substrate has a sheet thickness of 0.2 mm or less and comprises as the glass composition, in terms of mass %, 50% to 80% of SiO₂, 3% to 25% of Al₂O₃, 0% to 20% of B₂O₃, 0% to 25% of Li₂O+Na₂O+K₂O, 0% to 20% of MgO, 0% to 20% of CaO, 0% to 20% of SrO, 0% to 20% of BaO, 0% to 1% of As₂O₃, 0.0001% to 2% of SnO₂, and 0.005% to 10% of TiO₂.

4. The glass substrate for space solar power generation according to claim 1, wherein the glass substrate has a mass ratio SnO₂/(As₂O₃+SnO₂) of from 0.90 to 1 in the glass composition.

5. The glass substrate for space solar power generation according to claim 1, wherein when the sheet thickness is represented by “t” and a mass ratio SnO₂/(As₂O₃+SnO₂) in the glass composition is represented by A, the glass substrate has a ratio A/t of 1/mm or more.

6. The glass substrate for space solar power generation according to claim 1, wherein when a transmittance of the glass substrate at a wavelength of 300 nm at a thickness of 0.05 mm after irradiation with ultraviolet light at 254 nm (13 mW/cm²) for 23 hours is represented by t300 (%), and a transmittance of the glass substrate at a wavelength of 300 nm at a thickness of 0.05 mm before the irradiation with ultraviolet light is represented by T300 (%), the glass substrate has a value for T300-t300 of 3% or less.

7. The glass substrate for space solar power generation according to claim 1, wherein the glass substrate has a transmittance at a wavelength of 250 nm at a thickness of 0.05 mm of 30% or less.

8. The glass substrate for space solar power generation according to claim 1, wherein the glass substrate has an average transmittance at a wavelength of from 400 nm to 1,000 nm at a thickness of 0.05 mm of 90% or more.

9. The glass substrate for space solar power generation according to claim 1, wherein the glass substrate has a density of 2.80 g/cm³ or less.

10. The glass substrate for space solar power generation according to claim 1, wherein the glass substrate has a liquidus viscosity of 10^{4.0} dPa·s or more.

11. The glass substrate for space solar power generation according to claim 1, wherein the glass substrate has a coefficient of thermal expansion at from 30° C. to 380° C. of from 25×10⁻⁷/° C. to 90×10⁻⁷/° C.

12. The glass substrate for space solar power generation according to claim 1, wherein the glass substrate has a content of Fe₂O₃ of 500 ppm by mass or less.

13. The glass substrate for space solar power generation according to claim 1, wherein the glass substrate is formed by an overflow down-draw method.

14. The glass substrate for space solar power generation according to claim 1, wherein the glass substrate comprises as the glass composition, in terms of mass %, 50% to 80% of SiO₂, 3% to 20% of Al₂O₃, 0% to 20% of B₂O₃, 5% to 20% of Li₂O+Na₂O+K₂O, 0% to 20% of MgO, 0% to 20% of CaO, 0% to 20% of SrO, 0% to 20% of BaO, 0% to 1% of As₂O₃, 0.0001% to 2% of SnO₂, and 2% to 10% of TiO₂.

15. The glass substrate for space solar power generation according to claim 1, wherein the glass substrate has a sheet thickness of 0.2 mm or less and comprises as the glass composition, in terms of mass %, 50% to 80% of SiO₂, 3% to 25% of Al₂O₃, 0% to 20% of B₂O₃, 0.01% to 25% of Li₂O+Na₂O+K₂O, 0% to 20% of MgO, 0% to 20% of CaO, 0% to 20% of SrO, 0% to 20% of BaO, 0% to 1% of As₂O₃, 0.0001% to 2% of SnO₂, 0.001% to 10% of TiO₂, and 0.001% to 10% of CeO₂.

16. A glass substrate for space solar power generation, which has a sheet thickness of 0.2 mm or less and comprises as a glass composition, in terms of mass %, 54% to 80% of SiO₂, 4% to 25% of Al₂O₃, 0.1% to 20% of B₂O₃, 0% to 25% of Li₂O+Na₂O+K₂O, 0% to 20% of MgO, 0% to 20% of CaO, 0% to 20% of SrO, 0% to 20% of BaO, 0% to 1% of As₂O₃, 0.0001% to 2% of SnO₂, 0% to 10% of TiO₂, and 0.001% to 10% of CeO₂.
